(19) United States
(12) Patent Application Publication
(10) Pub. No.: US 2024/0332114 A1
(43) Pub. Date: Oct. 3, 2024

(54) SEMICONDUCTOR DEVICE WITH IMPROVED HEAT DISSIPATION AND METHOD FOR MAKING THE SAME

(71) Applicant: JCET STATS ChipPAC Korea Limited, Incheon (KR)

(72) Inventors: SeungHyun LEE, Incheon (KR); HeeSoo LEE, Incheon (KR); YongMoo SHIN, Incheon (KR)

(21) Appl. No.: 18/597,878

(22) Filed: Mar. 6, 2024

(30) Foreign Application Priority Data
Mar. 29, 2023 (CN) 202310325888.5

(51) Int. Cl. H01L 23/367; H01L 23/00; H01L 23/42; H01L 25/065

(52) U.S. Cl. CPC H01L 23/367; H01L 23/42; H01L 24/08; H01L 24/27; H01L 24/32; H01L 24/83; H01L 25/0657; H01L 2224/08145; H01L 2224/27; H01L 2224/32245; H01L 2224/83801; H01L 2225/06568

(57) ABSTRACT

A semiconductor device is provided. The semiconductor device includes a primary semiconductor die with a top surface, wherein the top surface comprising a first region and a second region besides the first region; an auxiliary semiconductor die attached onto the first region of the top surface of the primary semiconductor die; a thermally conductive laminated structure formed on the primary semiconductor die and the auxiliary semiconductor die, wherein the thermally conductive laminated structure at least partially covers the second region of the top surface of the primary semiconductor die, and at least partially covers a top surface of the auxiliary semiconductor die; and a heat spreader thermally coupled to the primary semiconductor die and the auxiliary semiconductor die through at least the thermally conductive laminated structure.

### TECHNICAL FIELD

The present application generally relates to semiconductor technology, and more particularly, to a semiconductor device with improved heat dissipation and a method for making a semiconductor device.

### BACKGROUND OF THE INVENTION

The semiconductor industry is constantly faced with complex integration challenges as consumers want their electronics to be smaller, faster and higher performance with more and more functionalities packed into a single device. In order to meet the needs of the consumers, more and more electronic components are tightly integrated. Yet, due to the tight integration, heat generated from an electronic component may be blocked by other electronic components, heat dissipation may not be ideal, and the performance of the semiconductor device may be harmed.

Therefore, a need exists for a semiconductor device with improved heat dissipation.

### SUMMARY OF THE INVENTION

An objective of the present application is to provide a semiconductor device with improved heat dissipation.

According to an aspect of embodiments of the present application, a semiconductor device is provided. The semiconductor device comprises a primary semiconductor die with a top surface, wherein the top surface comprising a first region and a second region besides the first region; an auxiliary semiconductor die attached onto the first region of the top surface of the primary semiconductor die; a thermally conductive laminated structure formed on the primary semiconductor die and the auxiliary semiconductor die, wherein the thermally conductive laminated structure at least partially covers the second region of the top surface of the primary semiconductor die, and at least partially covers a top surface of the auxiliary semiconductor die; and a heat spreader thermally coupled to the primary semiconductor die and the auxiliary semiconductor die through at least the thermally conductive laminated structure.

According to an aspect of embodiments of the present application, a method for making a semiconductor device is provided. The method may comprise: providing a semiconductor die stack with a primary semiconductor die and an auxiliary semiconductor die, wherein the primary semiconductor die comprises a top surface comprising a first region and a second region besides the first region, wherein the auxiliary semiconductor die is attached onto the first region of the top surface of the primary semiconductor die; forming a thermally conductive laminated structure on the semiconductor die stack, wherein the thermally conductive laminated structure at least partially covers the second region of the top surface of the primary semiconductor die, and at least partially covers a top surface of the auxiliary semiconductor die; and attaching a heat spreader on the semiconductor die stack through the thermally conductive laminated structure, so that the heat spreader is thermally coupled to the primary semiconductor die and the auxiliary semiconductor die through the thermally conductive laminated structure.

According to another aspect of embodiments of the present application, a method for making a semiconductor device is provided. The method may comprise: providing a semiconductor die stack with a primary semiconductor die and an auxiliary semiconductor die, wherein the primary semiconductor die comprises a top surface comprising a first region and a second region besides the first region, wherein the auxiliary semiconductor die is attached onto the first region of the top surface of the primary semiconductor die; forming an adhesion layer on the semiconductor die stack, wherein the adhesion layer at least partially covers the second region of the top surface of the primary semiconductor die and the top surface of the auxiliary semiconductor die; forming a first soldering type thermal interface layer on the second region of the top surface of the primary semiconductor die; attaching a thermally conductive block on the first soldering type thermal interface layer to form a flat top surface above the semiconductor die stack; forming a second soldering type thermal interface layer on the flat top surface above the semiconductor die stack; and attaching a lid onto the flat top surface above the semiconductor die stack to form a heat spreader at least using the lid and the thermally conductive block, wherein the lid is thermally coupled to the primary semiconductor die through the thermally conductive block, the first and second soldering type thermal interface layers and the adhesion layer, and thermally coupled to the auxiliary semiconductor die through the second soldering type thermal interface layer and the adhesion layer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B show cross-sectional views illustrating semiconductor devices according to two embodiments of the present application.

FIG. 2 shows a cross-sectional view illustrating a semiconductor device according to an embodiment of the present application.

FIGS. 3A and 3B show cross-sectional views illustrating semiconductor devices according to two embodiments of the present application.

FIG. 4 shows a cross-sectional view illustrating a semiconductor device according to an embodiment of the present application.

FIG. 5 is a flowchart of a method for making a semiconductor device according to an embodiment of the present application.

FIGS. 6A to 6E show cross-sectional views illustrating a method for making a semiconductor device according to an embodiment of the present application.

FIG. 6F shows a cross-sectional view illustrating a step of a method for making a semiconductor device according to another embodiment of the present application.

FIG. 7 is a flowchart of a method for making a semiconductor device according to another embodiment of the present application.

FIGS. 8A to 8G show cross-sectional views illustrating a method for making a semiconductor device according to another embodiment of the present application.

FIG. 8H shows a cross-sectional view illustrating a step of a method for making a semiconductor device according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

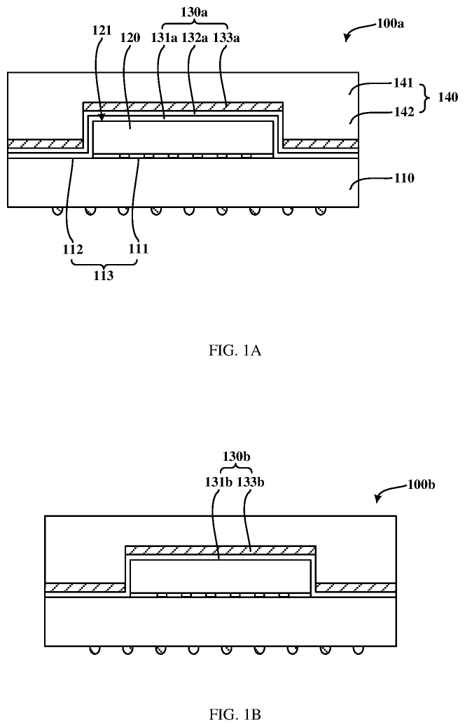

The present invention relates to semiconductor devices with improved thermal solution. FIGS. 1A and 1B show cross-sectional views illustrating semiconductor devices according to two embodiments of the present application. As shown in FIG. 1A, a semiconductor device 100a includes a primary semiconductor die 110 and an auxiliary semiconductor die 120 attached thereon. Specifically, the auxiliary semiconductor die 120 is attached to a first region 111 of a top surface 113 of the primary semiconductor die 110, and the auxiliary semiconductor die 120 does not cover a second region 112 of the top surface 113 of the primary semiconductor die 110. In some embodiments, the primary semiconductor die 110 is a logic chip and the auxiliary semiconductor die 120 is a memory chip. In some embodiments, the primary semiconductor die 110 and the auxiliary semiconductor die 120 are bonded together by hybrid bonding. In some embodiments, the hybrid bonding of the primary semiconductor die 110 and the auxiliary semiconductor die 120 can include a bonding surface (not shown) with a dielectric material and conductive interconnect structures that extend through the dielectric material. Preferably, the conductive interconnect structures may include copper posts. In some embodiments, the primary semiconductor die 110 may include through silicon vias (TSVs) (not shown) for desired vertical electrical connection.

Still referring to FIG. 1A, the semiconductor device 100a further includes a thermally conductive laminated structure 130a formed on the primary semiconductor die 110 and the auxiliary semiconductor die 120. The thermally conductive laminated structure 130a has a profile that generally conforms to that of the combined semiconductor dice 110 and 120. In some embodiments, the thermally conductive laminated structure 130a at least partially covers the second region 112 of the top surface 113 of the primary semiconductor die 110, and at least partially covers a top surface 121 of the auxiliary semiconductor die 120. Preferably, the thermally conductive laminated structure 130a fully covers the second region 112 of the primary semiconductor die 110 and the top surface 121 of the auxiliary semiconductor die 120. Specifically, the thermally conductive laminated structure 130a may include multiple thermally conductive layers formed on top of one another as illustrated in the following.

Still referring to FIG. 1A, the thermally conductive laminated structure 130a includes an adhesion layer 131a, a wetting layer 132a and a soldering type thermal interface layer 133a. The adhesion layer 131a is disposed for increasing adhesion between the semiconductor dice 110 and 120 with other layers. In some embodiments, the adhesion layer 131a is formed covering the second region 112 of the primary semiconductor die 110, the top surface 121 of the auxiliary semiconductor die 120, and the lateral surfaces of the auxiliary semiconductor die 120. In some embodiments, the adhesion layer 131a includes Ti, Ag, stainless steel (SUS) or a combination thereof. In some embodiments, the wetting layer 132a is formed on top of and covers a same area as the adhesion layer 131a. The wetting layer 132a may provide better wettability for the adhesion layer, and may facilitate a relatively complete and uniform adhesion of other layers on top of the wetting layer 132a. In some embodiments, the wetting layer 132a may contain one or more of the following materials: Cu, Ag or a combination thereof. Preferably, both the wetting layer and the adhesion layer have a depth under 2 um. In some embodiments, the soldering type thermal interface layer 133a is formed on the second region 112 of the primary semiconductor die 110 and on the top surface 121 of the auxiliary semiconductor die 120, that is, on top of the adhesion layer 131a and the wetting layer 132a formed on the primary semiconductor die 110 and the wetting layer 132a. In some other embodiments, the soldering type thermal interface layer 133a may also be at least partially formed on the lateral surface of the auxiliary semiconductor die 120 (not shown). In some embodiments, the soldering type thermal interface layer 133a may contain one or more of the following: In, Ag, or a combination thereof. The soldering type thermal interface layer 133a may be highly thermal conductive to facilitate heat dissipation. Preferably, the soldering type thermal interface layer 133a may have a higher thermal conductivity than other types of thermal interface layer such as epoxy type thermal interface layer. It can be understood that, in other embodiments, the adhesion layer 131a and/or the wetting layer 132a can be configured that it does not cover the lateral surface of the auxiliary semiconductor die 120.

Further, the semiconductor device 100a also includes a heat spreader 140 thermally coupled to the primary semiconductor die 110 and the auxiliary semiconductor die 120 through the thermally conductive laminated structure 130a. In some embodiments, the heat spreader 140 includes a lid 141 and a first plurality of lateral portions 142 extending from the lid 141. Preferably, the lid 141 and the first plurality of lateral portions 142 are integrally formed as a single piece. In some embodiments, the lid 141 is disposed on the auxiliary semiconductor die 120 and thermally coupled to the auxiliary semiconductor die 120 through the thermally conductive laminated structure 130a formed thereon. The first plurality of lateral portions 142 are attached onto and thermally coupled to the second region 112 of the primary semiconductor die 110 through the thermally conductive laminated structure 130a formed on the second region 112. It can be understood that, in other embodiments, the heat spreader 140 may take other shapes. There may be space between the heat spreader 140 and the semiconductor dice 110 and 120. It can be understood that, the heat spreader 140 may not include any lateral portion, or may include 1, 2, 3, or 4 lateral portions of the first plurality of lateral portions 142. The 4 lateral portions 142 may be connected to each other, forming a surrounding wall accommodating the auxiliary semiconductor die 120. In some embodiments, the primary semiconductor die 110 may be disposed with solder balls to achieve electrical connection with other components.

As illustrated above, the semiconductor device 100a includes the heat spreader 140 and the thermally conductive laminated structure 130a. Since the thermally conductive laminated structure 130a is in direct contact with the surface of the primary semiconductor die 110 and the auxiliary semiconductor die 120, heat generated by the semiconductor dice may be transferred efficiently through the highly thermally conductive structure 130a to the heat spreader 140. Therefore, the thermal dissipation of the semiconductor device 100a may be improved compared to conventional devices. The semiconductor device with improved thermal solution may also take other forms as illustrated below.

As shown in FIG. 1B, in a semiconductor device 100b similar to the semiconductor device 100a shown in FIG. 1A, the thermally conductive laminated structure 130b may include an adhesion layer 131b and a soldering type thermal interface layer 133b, without a wetting layer. Other aspects of the semiconductor device 100b may be referred to the semiconductor device 100a illustrated above.

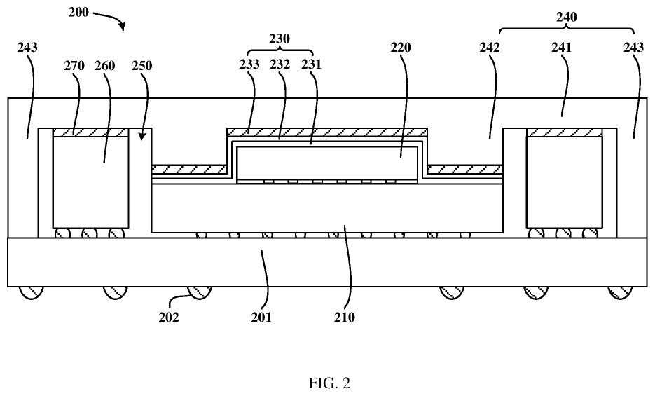

FIG. 2 shows a cross-sectional view illustrating a semiconductor device 200 according to another embodiment of the present application. Similar to the semiconductor device 100a illustrated above, the semiconductor device 200 includes a primary semiconductor die 210, an auxiliary semiconductor die 220 and a thermally conductive laminated structure 230. The thermally conductive laminated structure 230 includes an adhesion layer 231, a wetting layer 232 and a soldering type thermal interface layer 233. The configuration of the above-mentioned components may be referred to the illustration of the semiconductor device 100a shown in FIG. 1A.

Still referring to FIG. 2, different from the semiconductor device 100a shown in FIG. 1A, the semiconductor device 200 further includes a substrate 201 where the various components are mounted. In particular, the primary semiconductor die 210 is attached on a top surface of the substrate 201. Further, in the semiconductor device 200, a heat spreader 240 takes a different shape from the heat spreader 140 shown in FIG. 1A. Specifically, the heat spreader 240 includes a lid 241, a first plurality of lateral portions 242 and a second plurality of lateral portions 243. The configuration of the lid 241 and the first plurality of lateral portions 242 may be referred to the configuration of the heat spreader 140. The second plurality of lateral portions 243 extend from the lid 241 onto the top surface of the substrate 201 to support the heat spreader 240 on the substrate 201. The heat spreader 240 may include 1, 2, 3, or 4 lateral portions of the second plurality of lateral portions 243. The 4 lateral portions 243 may be connected to each other, forming a surrounding wall accommodating the primary semiconductor die 210 and the auxiliary semiconductor die 220. In some embodiments, the second plurality of lateral portions 243 are spaced apart from the first plurality of lateral portions 242 to form a cavity 250 therebetween. The semiconductor device 200 further includes at least one electronic component 260 received within the cavity 250 and attached on the substrate 201 via such as solder balls. The at least one electronic component 260 may be thermally coupled to the lid 241 of the heat spreader 240 such that heat can be dissipated from the package 260 to the lid 241. In some embodiments, the at least one electronic component 260 may be thermally coupled to the lid 241 via a thermally conductive layer 270. The thermally conductive layer 270 may include thermal greases, thermal adhesives, thermal gap fillers, liquid metal, and solder paste. In some embodiments, the thermally conductive layer 270 may include the same material as the soldering type thermal interface layer 233. In some embodiments, the thermally conductive layer 270 may include a different material from the soldering type thermal interface layer 233. It can be understood that, the thermally conductive layer 270 may be formed together with the soldering type thermal interface layer 233, or may be formed separately from the soldering type thermal interface layer 233. In some embodiments, the semiconductor device 200 may be have under solder balls 202 to achieve electrical connection with other devices.

In the above embodiments, the heat spreader may include various parts that are integrally formed as a single piece. In other embodiments, different parts of the heat spreader may be formed and/or disposed separately. The different parts may or may not be connected together by other components. Yet, different separate parts may together form the heat spreader for conducting heat to the external environment of the semiconductor device.

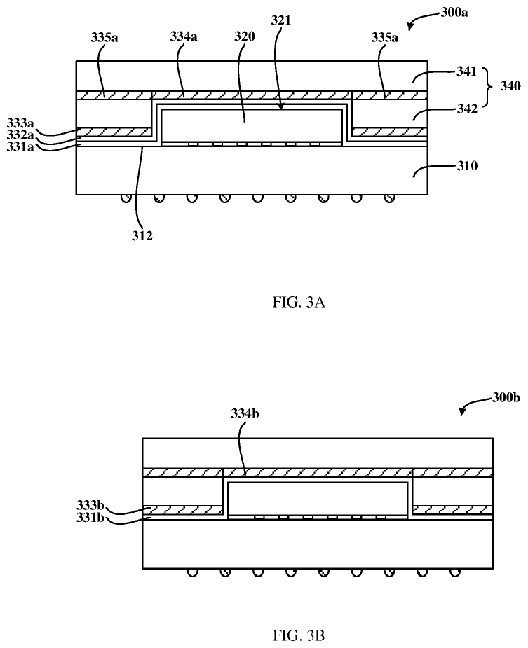

Referring to FIG. 3A, a semiconductor device 300a includes a primary semiconductor die 310 and an auxiliary semiconductor die 320 attached thereon. The illustration of the primary semiconductor die 310 and the auxiliary semiconductor die 320 may be referred to the primary semiconductor die 110 and the auxiliary semiconductor die 120 shown in FIG. 1A.

Still referring to FIG. 3A, the semiconductor device 300a further includes an adhesion layer 331a and a wetting layer 332a. In some embodiments, the adhesion layer 331a is formed covering a second region 312 of the primary semiconductor die 310, a top surface 321 of the auxiliary semiconductor die 320, and lateral surfaces of the auxiliary semiconductor die 320. In some embodiments, the adhesion layer 331a contains Ti, Ag, stainless steel (SUS) or a combination thereof. In some embodiments, the wetting layer 332a is formed on top of and covers a same area as the adhesion layer 331a. In some embodiments, the wetting layer 332a contains Cu, Ag or a combination thereof. It can be understood that, in other embodiments, the adhesion layer 331a and/or the wetting layer 332a can be configured that they do not cover the lateral surface of the auxiliary semiconductor die 320. In some embodiments, a soldering type thermal interface layer 333a is formed on the second region 312 of the primary semiconductor die 310, i.e., on top of the adhesion layer 331a and the wetting layer 332a formed thereon. In some embodiments, the soldering type thermal interface layer 333a contains In, Ag, or a combination thereof. The soldering type thermal interface layer 333a may be highly thermal conductive to facilitate heat dissipation. In some embodiments, another soldering type thermal interface layer 334a is formed over the top surface 321 of the auxiliary semiconductor die 320, i.e., on top of the adhesion layer 331a and the wetting layer 332a formed thereon. It can be understood that, the another soldering type thermal interface layer 334a may be formed with the soldering type thermal interface layer 333a, or formed separately from the soldering type thermal interface layer 333a. The another soldering type thermal interface layer 334a may include the same material as or different materials from the soldering type thermal interface layer 333a. The combination of the adhesion layer 331a, the wetting layer 332a, the soldering type thermal interface layer 333a and the another soldering type thermal interface layer 334a may form a thermally conductive laminated structure formed on the primary semiconductor die 310 and the auxiliary semiconductor die 320.

Still referring to FIG. 3A, in some embodiments, the semiconductor device 300a also includes a heat spreader 340. Specifically, the heat spreader 340 includes a lid 341 and a first plurality of lateral portions 342. The lid 341 is disposed on the auxiliary semiconductor die 320 and thermally coupled to the auxiliary semiconductor die 320 through the thermally conductive laminated structure formed thereon. The first plurality of lateral portions 342 are attached to and thermally coupled to the lid 341 through a thermally conductive layer 335a, and the first plurality of lateral portions 342 are attached onto and thermally coupled to the second region 312 of the primary semiconductor die 310 through the thermally conductive laminated structure formed thereon. The thermally conductive layer 335a may include thermal greases, thermal adhesives, thermal gap fillers, liquid metal, and solder paste. In some embodiments, the thermally conductive layer 335a is a soldering type thermal interface layer. It can be understood that, the thermally conductive layer 335a may be formed together with the another soldering type thermal interface layer 334a, or formed separately from the another soldering type thermal interface layer 334a. The thermally conductive layer 335a may include the same material as or different materials from the another soldering type thermal interface layer 334a. There may or may not be gap between the thermally conductive layer 335a and the another soldering type thermal interface layer 334a. In some embodiments, the another soldering type thermal interface layer 334a and the thermally conductive layer 335a are formed as a single layer on top of a flat surface above the auxiliary semiconductor die 320, i.e., formed at the same time with the same material. In FIG. 3A, the another soldering type thermal interface layer 334a and the thermally conductive layer 335a are illustrated separately mainly because they are at different locations with respect to the auxiliary semiconductor die 320. Other configurations of components of the semiconductor die 300a may be referred to the illustration of the semiconductor device 100a shown in FIG. 1A.

As shown in FIG. 3B, in a semiconductor device 300b similar to the semiconductor device 300a shown in FIG. 3A, the wetting layer may be omitted, and the thermally conductive laminated structure may include an adhesion layer 331b and a soldering type thermal interface layer 333b and another soldering type thermal interface layer 334b. Other aspects of the semiconductor device 300b may be referred to the semiconductor device 300a illustrated above with reference to FIG. 3A.

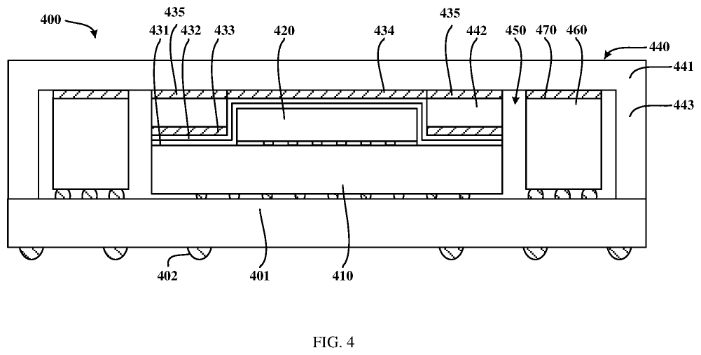

FIG. 4 shows a sectional view illustrating a semiconductor device 400 according to another embodiment of the present application. Similar to the semiconductor device 300a illustrated above with reference to FIG. 3A, the semiconductor device 400 includes a primary semiconductor die 410, an auxiliary semiconductor die 420, an adhesion layer 431, a wetting layer 432, a soldering type thermal interface layer 433, and another soldering type thermal interface layer 434. The configuration of the above-mentioned components may be referred to the illustration regarding the semiconductor device 300a shown in FIG. 3A. Different from the semiconductor device 300a, the semiconductor device 400 further includes a substrate 401. The configuration of the substrate 401 may be referred to the substrate 201 illustrated above with reference to FIG. 2. Also, the semiconductor device 400 includes a heat spreader 440 taking a different shape. Specifically, the heat spreader 440 includes a lid 441, a first plurality of lateral portions 442 and a second plurality of lateral portions 443. The first plurality of lateral portions 442 is attached to and thermally coupled to the lid 441 through a thermally conductive layer 435. The configuration of the lid 441, the first plurality of lateral portions 442 and the thermally conductive layer 435 may be referred to the illustration of the corresponding components in the semiconductor device 300a shown in FIG. 3A. The second plurality of lateral portions 443 extend from the lid 441 onto a top surface of the substrate 401 to support the heat spreader 440 on the substrate 401. The configuration of the second plurality of lateral portions 443 may be referred to the second plurality of lateral portions 243 illustrated above with reference to FIG. 2. In some embodiments, the second plurality of lateral portions 443 are spaced apart from the first plurality of lateral portions 442 to form a cavity 450 therebetween. The semiconductor device 400 further includes at least one electronic component 460 received within the cavity 450 and attached on the substrate 401 via such as solder balls. The at least one electronic component 460 may be thermally coupled to the lid 441 of the heat spreader 440. In some embodiments, the at least one electronic component 460 may be thermally coupled to the lid 441 via another thermally conductive layer 470. In some embodiments, the thermally conductive layer 470 may include the same material as the soldering type thermal interface layer 433, the another soldering type thermal interface layer 434, or the thermally conductive layer 435. In some embodiments, the thermally conductive layer 470 may include different material from any one of the above-mentioned layers. It can be understood that, the thermally conductive layer 470 may be formed together with the thermally conductive layer 435, or separately from the thermally conductive layer 435. In some embodiments, the semiconductor device 400 may be disposed with solder balls 402 to achieve electrical connection with other components.

FIG. 5 is a flowchart of a method 500 for making a semiconductor device according to an embodiment of the present application.

As shown in FIG. 5, in block 510, a semiconductor die stack with a primary semiconductor die and an auxiliary semiconductor die is provided. In block 520, a thermally conductive laminated structure is formed on the semiconductor die stack. In block 530, a heat spreader is attached on the semiconductor die stack through the thermally conductive laminated structure. The specific configurations of the steps in method 500 are illustrated as follows.

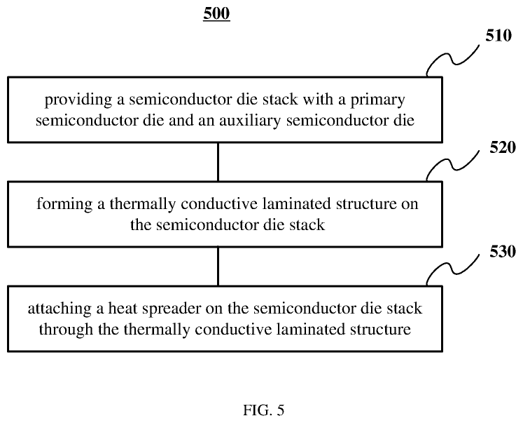

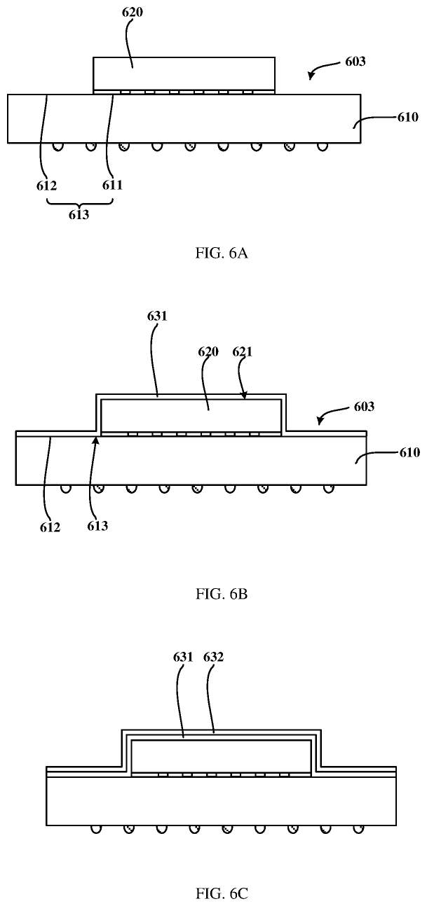

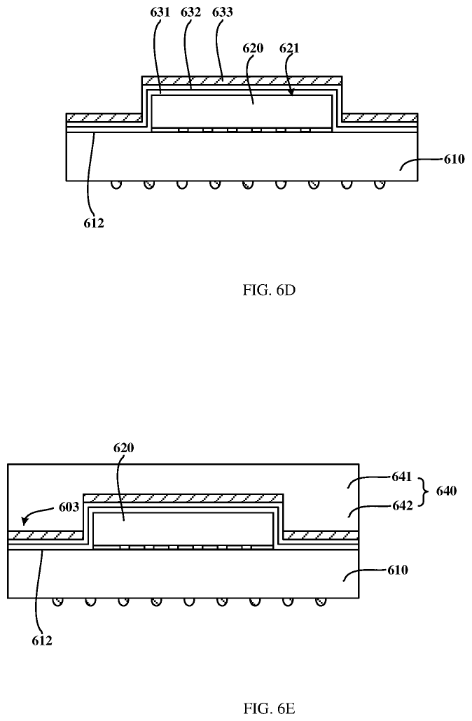

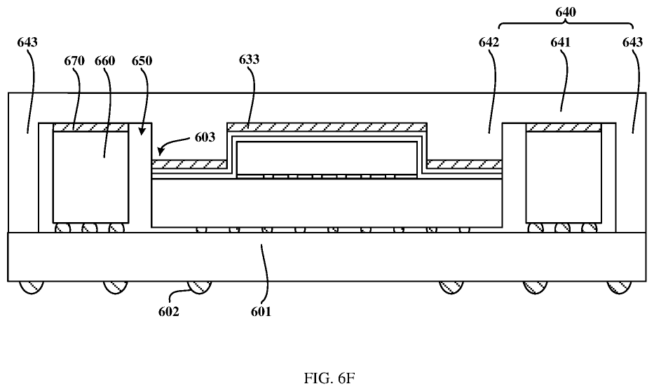

FIGS. 6A to 6E show cross-sectional views illustrating a method for making a semiconductor device according to an embodiment of the present application.

Referring to FIG. 6A, a semiconductor die stack 603 is provided comprising a primary semiconductor die 610 and an auxiliary semiconductor die 620. Specifically, the primary semiconductor die 610 includes a top surface 613 with a first region 611 and a second region 612 besides the first region 611. The auxiliary semiconductor die 620 is attached onto the first region 611 of the top surface 613 of the primary semiconductor die 610. In some embodiments, the primary semiconductor die 610 and the auxiliary semiconductor die 620 are bonded together by hybrid bonding.

Referring to FIG. 6B, an adhesion layer 631 is formed on top of the semiconductor die stack 603. The adhesion layer 631 at least partially covers the second region 612 of the top surface 613 of the primary semiconductor die 610, and at least partially covers a top surface 621 of the auxiliary semiconductor die 620. Preferably, the adhesion layer 631 fully covers the second region 612 of the primary semiconductor die 610 and the top surface 621 of the auxiliary semiconductor die 620. The adhesion layer 631 may be formed by a metal deposition process such as sputtering, electrolytic plating, and electroless plating. Preferably, the adhesion layer 631 is formed by sputtering Ti, Ag, stainless steel (SUS) or a combination thereof.

Referring to FIG. 6C, in some embodiments, a wetting layer 632 is formed on the adhesion layer 631. Preferably, the wetting layer 632 covers a same area as the adhesion layer 631. The wetting layer 632 may be formed by a metal deposition process such as sputtering, electrolytic plating, and electroless plating. Preferably, the wetting layer 632 is formed by sputtering Cu, Ag or a combination thereof. It can be understood that, this step may be omitted when the wetting layer 632 is omitted.

Referring to FIG. 6D, a soldering type thermal interface layer 633 is formed. Preferably, the soldering type thermal interface layer 633 is formed over the second region 612 of the primary semiconductor die 610 and over the top surface 621 of the auxiliary semiconductor die 620, i.e., on top of the adhesion layer 631 and the wetting layer 632 formed thereon. The soldering type thermal interface layer 633 may be formed by dispensing a soldering type thermal interface material, such as liquid metal and solder paste. Preferably, the soldering type thermal interface layer 633 is formed by disposing In, Ag, or a combination thereof, which may be further reflowed. In some embodiments, the adhesion layer 631, the wetting layer 632 and the soldering type thermal interface layer 633 may form a thermally conductive laminated structure. As illustrated above, in some embodiments, the wetting layer 632 may be omitted, the adhesion layer 631 and the soldering type thermal interface layer 633 may form the thermally conductive laminated structure.

Referring to FIG. 6E, a heat spreader 640 is attached on the semiconductor die stack 603 through the thermally conductive laminated structure. The heat spreader 640 is thermally coupled to the primary semiconductor die 610 and the auxiliary semiconductor die 620 through the above-mentioned thermally conductive laminated structure formed thereon. Specifically, the heat spreader 640 may include a lid 641 and a first plurality of lateral portions 642 extending therefrom. The lid 641 is disposed on the auxiliary semiconductor die 620, and the first plurality of lateral portions 642 are attached onto the second region 612 of the primary semiconductor die 610.

Referring to FIG. 6F, if the heat spreader 640 takes another form, the method may be adjusted accordingly. In some embodiments, apart from the lid 641 and the first plurality of lateral portions 642, the heat spreader 640 may also include a second plurality of lateral portions 643. The method may further include providing a substrate 601. Upon attaching the heat spreader 640 on the semiconductor stack 603, the second plurality of lateral portions 643 may be attached onto a top surface of the substrate 601 to support the heat spreader 640 on the substrate 601. In some embodiments, other electronic components 660 may be attached on the substrate 601, within a cavity 650 between the first and the second plurality of lateral portions 642 and 643. The attachment of the other electronic components 660 may be conducted at the same time as or at different times from the attachment of semiconductor stack 603. The other electronic components 660 may be formed with a thermally conductive layer 670. The thermally conductive layer 670 may be formed together with the soldering type thermal interface layer 633, or separately from the soldering type thermal interface layer 633. The materials of the two may be the same or different. In some embodiments, the substrate 601 may be disposed with solder balls 602 to achieve electrical connection with other components.

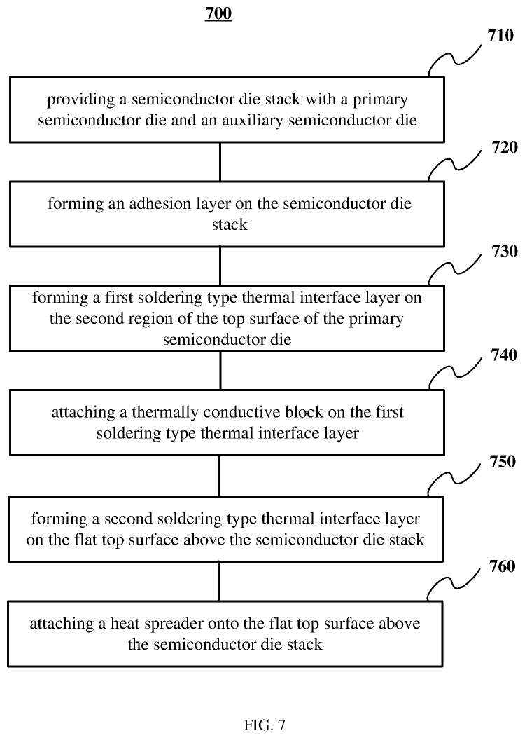

FIG. 7 is a flowchart illustrating a method 700 for making a semiconductor device according to another embodiment of the present application.

As shown in FIG. 7, in block 710, a semiconductor die stack with a primary semiconductor die and an auxiliary semiconductor die is provided. In block 720, an adhesion layer is formed on the semiconductor die stack. In block 730, a first soldering type thermal interface layer is formed on the second region of the top surface of the primary semiconductor die. In block 740, a thermally conductive block is attached on the first soldering type thermal interface layer. In block 750, a second soldering type thermal interface layer is formed on the flat top surface above the semiconductor die stack. In block 760, a heat spreader is attached on the flat top surface above the semiconductor die stack. The specific configurations of the steps in method 700 is illustrated as follows.

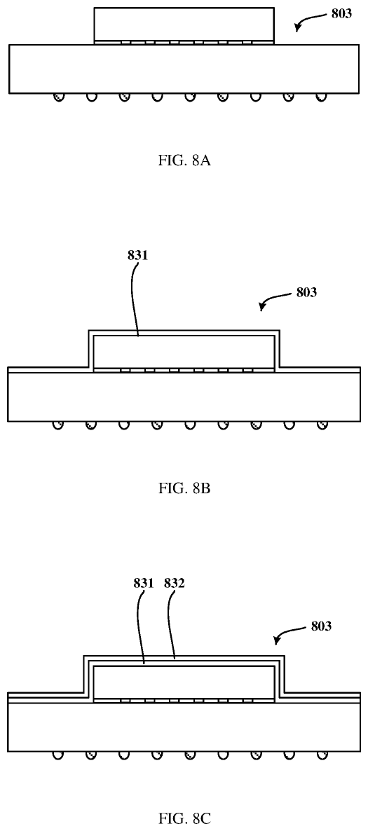

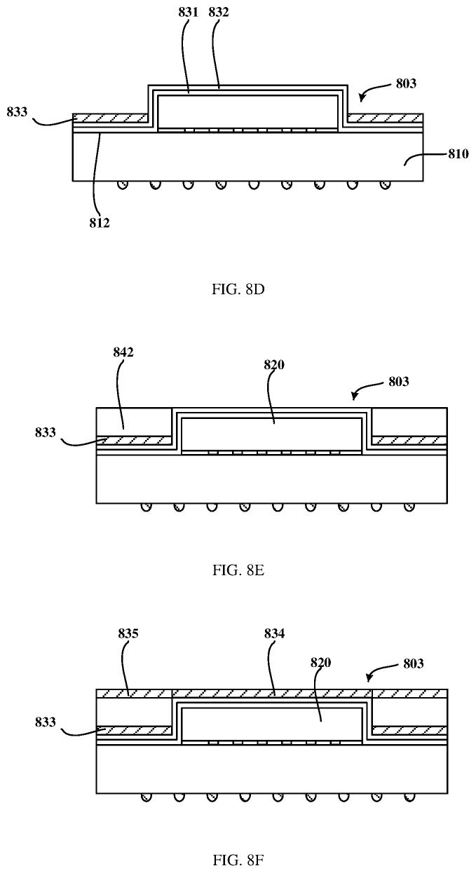

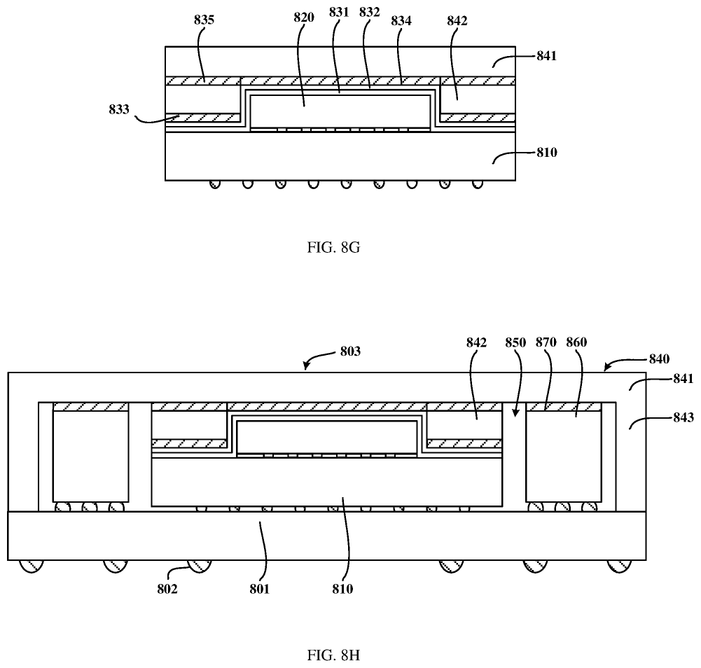

FIGS. 8A to 8G show cross-sectional views illustrating a method for making a semiconductor device according to another embodiment of the present application.

FIGS. 8A-8C are identical to FIGS. 6A-6C, which show the forming of the semiconductor die stack 803 and the two layers 831 and 832 formed thereon, respectively. The illustration may be referred to FIGS. 6A-6C.

Referring to FIG. 8D, a first soldering type thermal interface layer 833 is formed on the second region 812 of the top surface of the primary semiconductor die 810. That is to say, the first soldering type thermal interface layer 833 is formed on top of the adhesion layer 831 and, optionally, the wetting layer 832. The formation of the first soldering type thermal interface layer 833 may be referred to the illustration of the soldering type thermal interface layer 633 shown in FIG. 6D.

Referring to FIG. 8E, a thermally conductive block 842 is attached on the first soldering type thermal interface layer 833 to form a flat top surface above the semiconductor die stack 803. Preferably, the thermally conductive block fully surrounds the auxiliary semiconductor die 820. In other embodiments, the thermally conductive block 842 may partially surround the auxiliary semiconductor die 820, and a part of the total top surface above the semiconductor die stack 803 may form a flat top surface. In some embodiments, the thermally conductive block 842 may include multiple sub-blocks, such as 4 sub-blocks respectively disposed adjacent to the four lateral sides of the auxiliary semiconductor die 820. The multiple sub-blocks may include different materials, in some embodiments.

Referring to FIG. 8F, a second soldering type thermal interface layer is formed on the flat top surface above the semiconductor die stack 803. Specifically, the second soldering type thermal interface layer may include a region 834 on top of the auxiliary semiconductor die 820 and a region 835 on top of the thermally conductive block 842. The material and/or formation of the second soldering type thermal interface layer may be the same as or different from the first soldering type thermal interface layer 833. In some embodiments, the regions 834 and 835 are formed simultaneously with the same material.

Referring to FIG. 8G, a lid 841 is attached onto the flat top surface above the semiconductor die stack 803. Specifically, the lid 841 is attached onto the region 834 of the second soldering type thermal interface layer, and therefore, the lid 841 is thermally coupled to the auxiliary semiconductor die 820 through the region 834 of the second soldering type thermal interface layer, the wetting layer 832 and the adhesion layer 831. Also, the lid 841 is attached onto the region 835 of the second soldering type thermal interface layer, and therefore, the lid 841 is thermally coupled to the primary semiconductor die 810 through the region 835 of the second soldering type thermal interface layer, thermally conductive block 842, the first soldering type thermal interface layer 833, the wetting layer 832 and the adhesion layer 831. It can be understood that, the material of the lid 841 may be the same as or different from the thermally conductive block 842. It can be understood that, the wetting layer 832 may be omitted.

Referring to FIG. 8H, if the heat spreader 840 takes another form, the method may be adjusted accordingly. In some embodiments, apart from the lid 841 and the thermally conductive block 842, the heat spreader 840 may also include a plurality of lateral portions 843. The method may further include providing a substrate 801. Upon attaching the lid 841 onto the flat top surface above the semiconductor die stack 803, the plurality of lateral portions 843 may be attached onto a top surface of the substrate 801 to support the heat spreader 840 on the substrate 801. In some embodiments, other electronic components 860 may be attached on the substrate 801 within a cavity 850 between the thermally conductive block 842 and the plurality of lateral portions 843. The other electronic components 860 may be formed with a thermally conductive layer 870. Other aspects regarding the semiconductor device may be referred to the illustration of FIG. 6F.

It can be understood that, the size of components and the height of the layers are only for illustration, not representing the actual proportion of the layers.

It can be understood that, the electronic component 260, 460, 660, 860 may be a package.

The discussion herein included numerous illustrative figures that showed various portions of a semiconductor device and method for making the semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor device, comprising:
a primary semiconductor die with a top surface, wherein the top surface comprising a first region and a second region besides the first region;
an auxiliary semiconductor die attached onto the first region of the top surface of the primary semiconductor die;
a thermally conductive laminated structure formed on the primary semiconductor die and the auxiliary semiconductor die, wherein the thermally conductive laminated structure at least partially covers the second region of the top surface of the primary semiconductor die, and at least partially covers a top surface of the auxiliary semiconductor die; and
a heat spreader thermally coupled to the primary semiconductor die and the auxiliary semiconductor die through at least the thermally conductive laminated structure.

2. The semiconductor device of claim 1, wherein the thermally conductive laminated structure comprises a soldering type thermal interface layer and an adhesion layer.

3. The semiconductor device of claim 1, wherein the primary semiconductor die and the auxiliary semiconductor die are bonded together by hybrid bonding.

4. The semiconductor device of claim 1, wherein the heat spreader comprises:
a lid disposed on the auxiliary semiconductor die and thermally coupled to the auxiliary semiconductor die through the thermally conductive laminated structure formed thereon, and
a first plurality of lateral portions that extend from the lid, and attached onto and thermally coupled to the second region of the primary semiconductor die through the thermally conductive laminated structure formed thereon,
and wherein the lid and the first plurality of lateral portions are integrally formed as a single piece.

5. The semiconductor device of claim 4, further comprising:
a substrate, wherein the primary semiconductor die is attached on a top surface of the substrate;
and wherein the heat spreader further comprises a second plurality of lateral portions that extend from the lid onto the top surface of the substrate to support the heat spreader on the substrate.

6. The semiconductor device of claim 5, wherein the second plurality of lateral portions are spaced apart from the first plurality of lateral portions to form a cavity therebetween, the semiconductor device further comprises at least one electronic component received within the cavity and attached on the substrate, and wherein the at least one electronic component is thermally coupled to the lid of the heat spreader.

7. The semiconductor device of claim 1, wherein the heat spreader comprises:
a lid disposed on the auxiliary semiconductor die and thermally coupled to the auxiliary semiconductor die through the thermally conductive laminated structure formed thereon, and
a first plurality of lateral portions attached to and thermally coupled to the lid through a thermally conductive layer, and attached onto and thermally coupled to the second region of the primary semiconductor die through the thermally conductive laminated structure formed thereon.

8. The semiconductor device of claim 7, further comprising:
a substrate, wherein the primary semiconductor die is attached on a top surface of the substrate;
and wherein the heat spreader further comprises a second plurality of lateral portions that extend from the lid onto the top surface of the substrate to support the heat spreader on the substrate.

9. The semiconductor device of claim 8, wherein the second plurality of lateral portions are spaced apart from the first plurality of lateral portions to form a cavity therebetween, the semiconductor device further comprises at least one electronic component received within the cavity and attached on the substrate, and wherein the at least one electronic component is thermally coupled to the lid of the heat spreader.

10. The semiconductor device of claim 7, wherein the thermally conductive layer is a soldering type thermal interface layer.

11. A method for forming a semiconductor device, comprising:
providing a semiconductor die stack with a primary semiconductor die and an auxiliary semiconductor die, wherein the primary semiconductor die comprises a top surface comprising a first region and a second region besides the first region, wherein the auxiliary semiconductor die is attached onto the first region of the top surface of the primary semiconductor die;
forming a thermally conductive laminated structure on the semiconductor die stack, wherein the thermally conductive laminated structure at least partially covers the second region of the top surface of the primary semiconductor die, and at least partially covers a top surface of the auxiliary semiconductor die; and
attaching a heat spreader on the semiconductor die stack through the thermally conductive laminated structure, so that the heat spreader is thermally coupled to the primary semiconductor die and the auxiliary semiconductor die through the thermally conductive laminated structure.

12. The method of claim 11, wherein forming a thermally conductive laminated structure comprises forming an adhesion layer and forming a soldering type thermal interface layer.

13. The method of claim 11, wherein the primary semiconductor die and the auxiliary semiconductor die are bonded by hybrid bonding.

14. The method of claim 11, wherein the heat spreader comprises a lid and a first plurality of lateral portions extending from the lid, wherein the lid and the first plurality of lateral portions are integrally formed as a single piece, and
wherein attaching a heat spreader on the semiconductor die stack comprises:
disposing the lid on the auxiliary semiconductor die, so that the lid is thermally coupled to the auxiliary semiconductor die through the thermally conductive laminated structure formed thereon and
attaching the first plurality of lateral portions onto the second region of the primary semiconductor die, so that the first plurality of lateral portions are thermally coupled to the second region of the primary semiconductor die through the thermally conductive laminated structure formed thereon.

15. The method of claim 14, further comprising:
providing a substrate; and
attaching the primary semiconductor die on a top surface of the substrate;
wherein the heat spreader further comprises a second plurality of lateral portions extending from the lid; and
wherein attaching a heat spreader on the semiconductor die stack further comprises: attaching the second plurality of lateral portions onto the top surface of the substrate to support the heat spreader on the substrate.

16. A method for forming a semiconductor device, comprising:
providing a semiconductor die stack with a primary semiconductor die and an auxiliary semiconductor die, wherein the primary semiconductor die comprises a top surface comprising a first region and a second region besides the first region, wherein the auxiliary semiconductor die is attached onto the first region of the top surface of the primary semiconductor die;
forming an adhesion layer on the semiconductor die stack, wherein the adhesion layer at least partially covers the second region of the top surface of the primary semiconductor die and the top surface of the auxiliary semiconductor die;
forming a first soldering type thermal interface layer on the second region of the top surface of the primary semiconductor die;
attaching a thermally conductive block on the first soldering type thermal interface layer to form a flat top surface above the semiconductor die stack;
forming a second soldering type thermal interface layer on the flat top surface above the semiconductor die stack; and
attaching a lid onto the flat top surface above the semiconductor die stack to form a heat spreader at least using the lid and the thermally conductive block, wherein the lid is thermally coupled to the primary semiconductor die through the thermally conductive block, the first and second soldering type thermal interface layers and the adhesion layer, and thermally coupled to the auxiliary semiconductor die through the second soldering type thermal interface layer and the adhesion layer.

17. The method of claim 16, wherein after forming an adhesion layer on the semiconductor die stack, further comprising:
forming a wetting layer on the semiconductor die stack; and
in the step of attaching a lid onto the flat top surface above the semiconductor die stack, the lid is thermally coupled to the primary semiconductor die further through the wetting layer, and thermally coupled to the auxiliary semiconductor die further through the wetting layer.

18. The method of claim 16, wherein the primary semiconductor die and the auxiliary semiconductor die are bonded by hybrid bonding.

19. The method of claim 16, further comprising:
providing a substrate; and
attaching the primary semiconductor die on a top surface of the substrate;
wherein the heat spreader further comprises a plurality of lateral portions; and
wherein attaching a lid onto the flat top surface above the semiconductor die stack further comprises: attaching the plurality of lateral portions onto the top surface of the substrate to support the heat spreader on the substrate.
